(19) United States
(12) Patent Application Publication
(10) Pub. No.: US 2022/0292418 A1
(43) Pub. Date: Sep. 15, 2022

(54) OPERATION RISK EVALUATION SYSTEM, MODEL CREATION APPARATUS, OPERATION RISK EVALUATION METHOD, AND RECORDING MEDIUM

(71) Applicant: Hitachi, Ltd., Tokyo (JP)

(72) Inventors: Kei UTSUGI, Tokyo (JP); Issei SUEMITSU, Tokyo (JP); Sanato OHTOSHI, Tokyo (JP); Yutaka NAGAI, Tokyo (JP)

(21) Appl. No.: 17/678,778

(22) Filed: Feb. 23, 2022

(30) Foreign Application Priority Data
Mar. 15, 2021 (JP) 2021-041620

(51) Int. Cl. G06Q 10/06; G06N 3/04

(52) U.S. Cl. CPC G06Q 10/0635; G06N 3/0472

(57) ABSTRACT

An operation risk evaluation system includes: a model storage unit configured to store a surrogate model that is a learned model of a relationship between an input that is a first feature amount of the operation and an output that is a second feature amount of the operation calculated by a predetermined simulation of one of the steps, the learned model being configured to surrogate for the predetermined simulation in which an output corresponding to an input having the same value has indeterminity different for each input; a prediction unit configured to predict a plurality of the second feature amounts having indeterminity corresponding to the first feature amount having the same value in the step; and a risk evaluation unit configured to evaluate a risk of the operation in the step based on the plurality of second feature amounts having indeterminity predicted by the prediction unit.

### BACKGROUND OF THE INVENTION

### 1. Field of the Invention

The present invention relates to an operation risk evaluation system, a model creation apparatus, an operation risk evaluation method, and a recording medium storing an operation risk evaluation program.

### 2. Description of the Related Art

There is a system that evaluates an operation plan including a plurality of steps based on future prediction. For example, there is a simulation system in which a future trend in a project including a plurality of steps is predicted using performance information up to a present time and future prediction information, risk evaluation of the project is performed based on a prediction result, and an evaluation result is presented to a user (see JP-A-2004-192109 (PTL 1)).

Further, in recent years, a supply chain has been constructed across different types of systems and a plurality of organizations. In such a situation, when a productivity of any of the steps is reduced and a delay occurs due to a problem such as a manual operation, a mismatch between systems, or a facility failure, it is necessary to correct the entire operation plan.

There is further a monitoring system called a dashboard that simulates a future trend in what an influence of a correction of an operation plan would be and presents a simulation result to a user (see “Learn from Actual Example|Points to Keep in Mind when Creating Management Dashboard”, [online], FineReport Software Co., Ltd., [searched on March 10, Internet <URL: https://www.fineport.com/jp/analysis/normstarmetrics/> (NON-PTL 1).

In these techniques in the related art, a future trend simulation is performed on an assumption that steps progress at a standard pace.

Here, there is an uncertainty that a delay of steps due to an occurrence of various problems affects subsequent steps and delays an overall operation plan. However, since such an uncertainty is not considered in the above-described related art, it is difficult to quickly perform simulation and risk evaluation of an operation plan in a realistic calculation time in which a pattern is complicated by considering fluctuation of the uncertainty. When considering the fluctuation of the uncertainty, it is difficult to present an evaluation result of a risk of the operation plan based on the simulation in which the pattern is complicated to the user for intuitively grasping an evaluation result.

The invention has been made in consideration of the above problem, and an object of the invention is to quickly perform simulation and risk evaluation in consideration of an uncertainty due to occurrence of a problem in risk evaluation of an operation including steps.

### SUMMARY OF THE INVENTION

In order to solve the problem described above, one aspect of the invention provides an operation risk evaluation system for performing risk evaluation of an operation including steps. The system includes: a model storage unit configured to store a surrogate model that is a learned model of a relationship between an input that is a first feature amount of the operation and an output that is a second feature amount of the operation calculated by a predetermined simulation of one of the steps, the learned model being configured to surrogate for the predetermined simulation in which an output corresponding to an input having the same value has indeterminity different for each input; a prediction unit configured to predict a plurality of the second feature amounts having indeterminity corresponding to the first feature amount having the same value in the step by repeatedly acquiring the second feature amount as the output from the surrogate model with the first feature amount as the input for a predetermined number of trials on the first feature amount having the same value; and a risk evaluation unit configured to evaluate a risk of the operation in the step based on the plurality of second feature amounts having indeterminity predicted by the prediction unit.

According to the invention, for example, in risk evaluation of an operation including steps, it is possible to quickly perform simulation and risk evaluation in consideration of an uncertainty due to an occurrence of a problem.

### BRIEF DESCRIPTION OF THE DRAWINGS

FIG. 1 is a diagram showing an example of an operation including a plurality of steps having a hierarchical structure;

FIG. 2 is a diagram schematically showing an example of a progress status of an operation having an uncertainty;

FIG. 3 is a diagram schematically showing an example of a prediction simulation of an operation schedule performed using two methods according to an embodiment;

FIG. 4 is a diagram showing an example of a problem event;

FIG. 5 is a diagram showing an example of input and output of a surrogate simulation of each step;

FIG. 6 is a diagram showing a configuration of an overall system according to an embodiment;

FIG. 7 is a flowchart showing an example of surrogate model creation processing in a preliminary phase;

FIG. 8 is a flowchart showing an example of risk analysis processing in an operation phase;

FIG. 9 is a diagram showing a terminal display example of a dashboard of a risk analysis result;

FIG. 10 is a diagram showing a terminal display example of the dashboard of the risk analysis result;

FIG. 11 is a diagram showing a terminal display example of the dashboard of the risk analysis result; and

FIG. 12 is a diagram showing a hardware configuration example of a computer.

### DESCRIPTION OF THE PREFERRED EMBODIMENTS

Hereinafter, an embodiment of the invention will be described with reference to the following description or drawings. Configurations, processing, specific items of data, the number of elements, and the like shown in the invention are not limited to the embodiment described herein, and appropriate combinations and improvements can be made without changing the gist. Elements that are not directly related to the present embodiment are not shown.

In the following description, the same or similar components are distinguished by reference numerals with suffixes, and the same or similar components are collectively referred to by reference numerals without suffixes.

### (Plurality of Steps Having Hierarchical Structure)

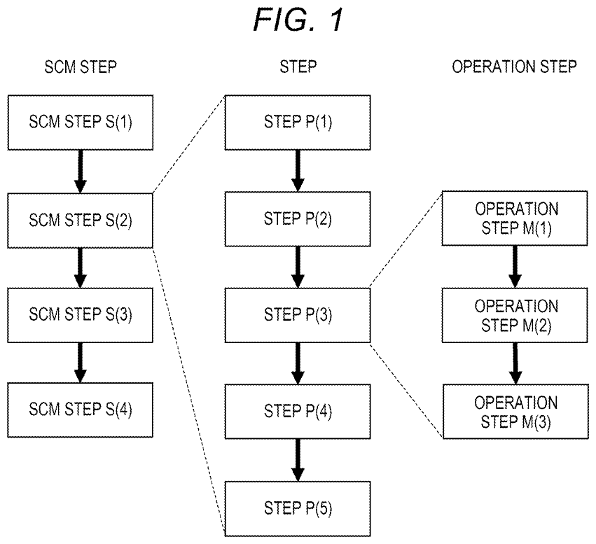

FIG. 1 is a diagram showing an example of an operation (for example, an operation in warehouse work, an operation in product manufacturing work) performed by a plurality of steps having a hierarchical structure. As shown in FIG. 1, the operation is performed in an order of supply chain management (SCM) steps S(1), S(2), S(3), and S(4). For example, in the SCM step S(2), the operation is performed in an order of steps P(1), P(2), P(3), P(4), and P(5) in a lower hierarchy. Further, for example, in the step P(3), the operation is performed in an order of operation steps M(1), M(2), and M(3) in a lower hierarchy. An output of each step is input to a subsequent step. Although in FIG. 1, each of the SCM step S(2) and the step P(3) includes steps in a lower hierarchy, the same applies to other SCM steps and steps. Hereinafter, a step P(n) (n=1, 2, 3, 4, 5) will be described as an example.

### (Progress Status of Operation Having Uncertainty)

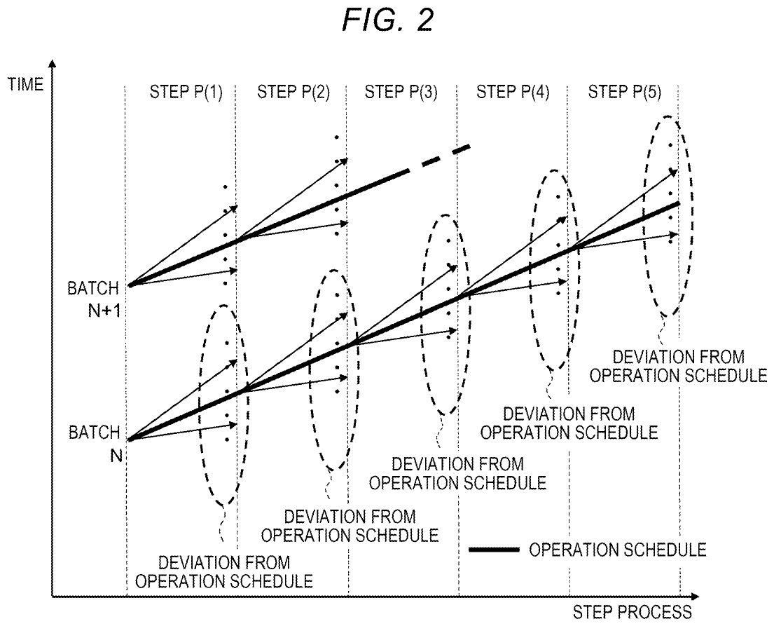

FIG. 2 is a diagram schematically showing an example of a progress status of an operation having uncertainty. The operation including one or more steps is performed in accordance with an optimized operation schedule. The operation schedule includes resource allocation of operation machines and operators, operation start time of the operation machines and the operators, and the like, which are created based on an operation plan including a predicted value.

However, in practice, a problem may occur in each step, and a plurality of patterns may deviate from the operation schedule (advance and delay of the actual operation progress, portions surrounded by broken lines that are schedule deviations in FIG. 2). The deviation of the plurality of patterns is uncertainty (indeterminity) of the operation progress (operation required time, operation end time, and the like). In the deviation from the operation schedule, a schedule delay in which operation time is longer than that of the operation schedule is a problem.

In general step management, a surplus buffer is placed in each step stage, and scheduling management is performed so that an error within a predetermined range is absorbed within a buffer range. Only when the deviation of the plan due to the delay exceeds the buffer range, it is determined as the schedule delay, and by dynamically managing the surplus buffer, the operation schedule may be finely optimized.

Here, in general, the schedule delay in each step is related to the previous and subsequent steps. That is, a schedule delay occurring in a certain step may spread to a subsequent step and cause a schedule delay of the subsequent step. In addition, the operation schedule itself may need to be reviewed due to a chain risk that affects not only an immediately subsequent step but also subsequent steps and causes a chain schedule delay.

In order to avoid the chain risk in advance, it is desirable to perform future prediction including the deviation from the operation schedule by an agent simulation in consideration of an occurrence of various problems that may cause an operation schedule delay in each step of the operation schedule. However, when the future prediction of the operation schedule is performed by the agent simulation with various variations in consideration of uncertainty of a problem occurring among a large number of problems, an amount of calculation is enormous, and thus there is a problem of calculation time that a calculation speed of a computer is insufficient and an operation within practical time is impossible.

### (Simulation Using Two Methods)

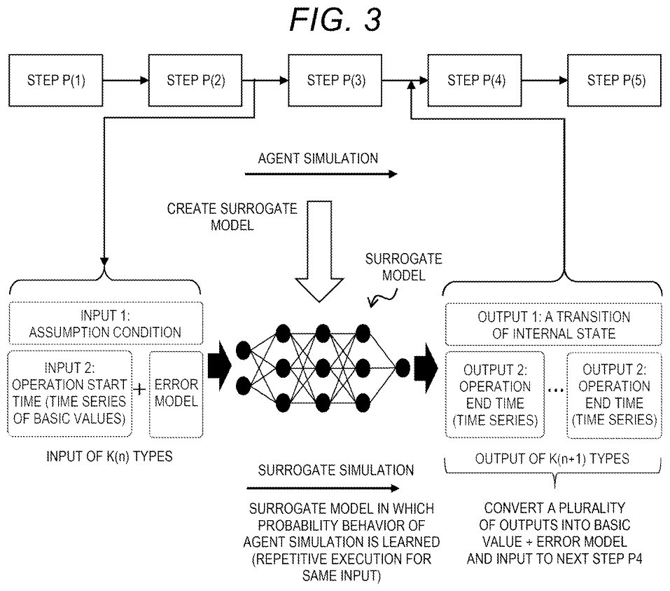

Therefore, in the present embodiment, the problem of calculation time described above is solved by using two simulation methods including an agent simulation in an upper hierarchy and a surrogate simulation in a lower hierarchy in a hierarchical simulation structure. FIG. 3 is a diagram schematically showing an example of a prediction simulation of an operation schedule performed using two methods in the present embodiment. In the present embodiment, the steps P(1) to P(5) are upper hierarchical steps, and the operation steps M(1) to M(3) are lower hierarchical steps.

In the agent simulation, an operation logic and an internal state are expressed in a form that can be understood by a human being, and various internal states and transitions thereof of each step P(n) that appear due to a behavior and an interaction of an agent in each step can be simulated under a predetermined constraint condition.

Specifically, in the agent simulation, the operation time is calculated by decomposing the operation into elements and allocating required time of the elements along a time axis. Simulation calculation of an accuracy of the operation, a failure rate, and the like may also be performed in consideration of randomness based on a relationship of the operation.

As described above, in the agent simulation, it is possible to reproduce a part of various events and problems occurring during operation. For example, a calculation of a queue generated by overlapping operation time of a plurality of autonomous bodies, a condition of a physically calculated operation target object, an operation failure rate based on a required accuracy and an operation difficulty level is performed, and a difference in the required time generated as a result is calculated. However, in the agent simulation, the more diversified a problem occurring at the time of operation, the more difficult to complete a prediction within a practical calculation time.

On the other hand, in the proxy simulation, a similar calculation result can be simulated at a high speed by substituting for calculation of the agent simulation using a surrogate model obtained by learning an output of the agent simulation in response to an input in each step P(n).

When a probabilistic indefinite element (random variable or the like) is included in a behavior or an interaction of an agent, the surrogate model probabilistically behaves on the same input and returns outputs of a plurality of patterns. For example, when a task input to the step P(n) has a specific feature amount (for example, operation start time, product accuracy), the calculation in which the same task is used as an input of the surrogate model is repeated. Then, as a processing result of the same task, feature amounts (operation end time, operation result accuracy, and the like) of a plurality of patterns corresponding to the number of repetitions are output. When the feature amounts of a plurality of patterns are input to a next step P(n+1), fluctuations of the feature amounts (operation end time, operation result accuracy, and the like) are maintained.

For example, as shown in FIG. 3, it is considered that an input 1: assumption condition, and an input 2: operation start time (time series of basic values) and operation start time that is one of a plurality of patterns created from an error model are input to the surrogate model of the step P(3). In this case, the surrogate model outputs a plurality of (K(n+1) types) outputs 2: operation end time (time series) together with an output 1: transition of internal state in response to the input. By repeating the processing from the input to the output for K(n) types of inputs with the surrogate model, it is possible to obtain outputs of a plurality of patterns corresponding to inputs of a plurality of patterns.

The fluctuations of the feature amounts (operation end time, operation result accuracy, and the like) that are inputs and outputs of each step can be held as a case list including values of a plurality of patterns or a probability distribution model. In the present embodiment, the fluctuations of the feature amounts (operation end time, operation result accuracy, or the like) of each step are expressed using a set of results of a plurality of patterns obtained by performing calculation processing with a surrogate model including a probabilistic operation element for one input.

As a learned model including such a probabilistic operation element, for example, a method in which the learned model is implemented by a Bayesian neural network is known. In a normal neural network, as a result of machine learning, the same output is always returned to the same input. In the Bayesian neural network, a coupling coefficient is expressed not as a numerical value but as a distribution, and different output results are returned for the same input. By using this characteristic, it is possible to reproduce a behavior (probability distribution) in which a result stochastically shows fluctuation for the same input.

However, the present embodiment is not limited to the agent simulation as long as it is a method capable of simulating various internal states and transitions thereof in each step P(n) as in the agent simulation. The learning method and the learned model are not limited to the Bayesian neural network as long as the learning method and the learned model can return a plurality of outputs with a behavior based on a probabilistic distribution for the same input.

### (Example of Problem Event)

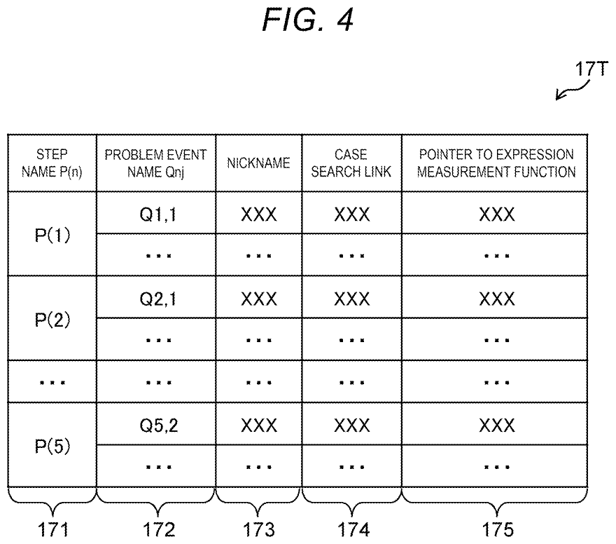

FIG. 4 is a diagram showing an example of a problem event. In the present embodiment, a typical pattern of a “problem event” is specifically defined in advance. The “problem event” is an internal state corresponding to a state variable designated in advance as having a risk of causing a problem such as deterioration of productivity in executing the step P(n). When learning a surrogate model, learning is performed by assigning a flag to a state having a state variable of each step corresponding to a problem event in an agent simulation under a predetermined assumption condition.

Specifically, among behaviors of the step P(n), information for grouping and managing characteristic states as “problem events” is held. One or more problem events Qn,j (j=1, 2, . . . ) are held for each step P(n), in which n is an index for identifying a step, and j is an index for identifying a problem event in the same step P(n).

As shown in FIG. 4, in a problem event table 17T, a step name 171, a problem event name 172, a nickname 173, a case search link 174, and a pointer 175 to an expression measurement function are stored in association with each other as a definition of a problem event. The nickname 173 is information representing the problem event in a format that can be understood by a person. The case search link 174 stores a search link to a specific case of the problem event in the agent simulation. The pointer 175 to the expression measurement function stores a pointer to a procedure function for measuring an expression of the problem event in the agent simulation. An information format of the problem event is not limited to a table format.

Hereinafter, an example of a problem event in operation management of a factory or a warehouse will be described. The problem event may be a case that occurs due to an input factor such as an input amount, or due to a completely accidental probability.
Decrease in productivity due to congestion of conveyor
Occurrence of temporary saving operation due to overflow of an operation buffer provided to absorb a delay of an operation schedule
Delay of predetermined time (for example, 15 minutes) or more with respect to scheduled time
Time required to reach final shipping time is less than predetermined time (for example, 30 minutes)
Delay in operation productivity due to temporary resource shortage
Re-operation of returning to a previous step due to break of target object
Stop of part of machine due to machine wear

### (Input and Output of Surrogate Simulation of Each Step)

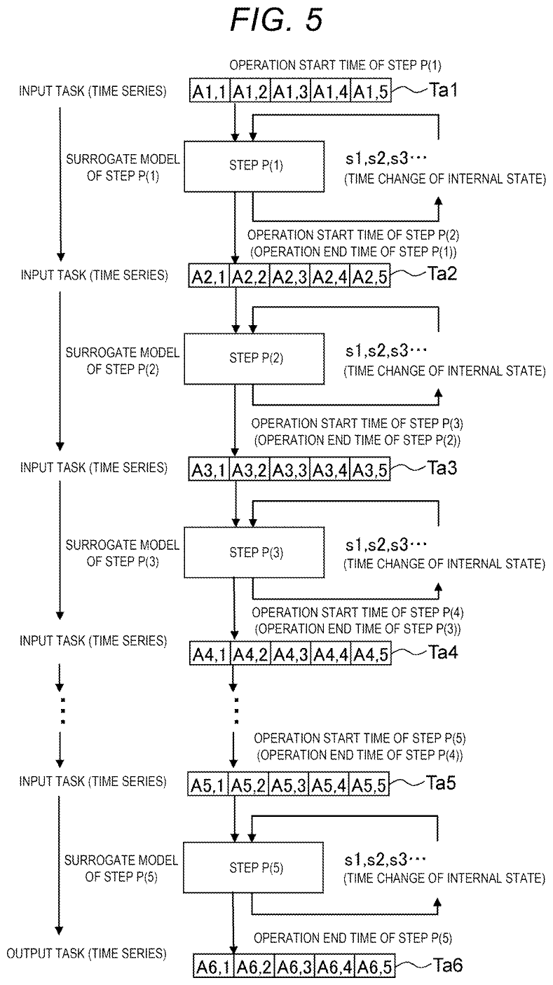

FIG. 5 is a diagram showing an example of input and output of a surrogate simulation of each step. As shown in FIG. 5, information on a task input to the step P(n) (n=1 to 5) is held as time series data (time transition model) An,k (k=1, 2, . . . ). Each step P(n) has variables (s1, s2, s3, . . . ) of the internal state, and the productivity changes according to the variables. Although a task Tal input to the surrogate model for predicting an operation result in the step P(1) is single, a task Tan input to the step P(n) (n=2 to 5) is a set of patterns of K(n) types (K(n)>1). This is because the fluctuation of the state occurs due to uncertainty during the period of the step before the step P(n) (n=2 to 5).

K(n) types of tasks Tan are available as task candidates input to each surrogate model for predicting the operation results of the step P(n) (n=2 to 5). Each task represents a series of batch operations, and is time series data reflecting the start time and the state of each operation performed with passage of time. Then, one task input to the step P(n) is randomly sampled from the task Tan. By performing the surrogate simulation (neural network processing of the surrogate model) of the step P(n) a plurality of times on one piece of sampling data, behavior examples that are slightly different from each other are obtained.

As described above, as the output of the step P(n) (n=1 to 5), the fluctuation in the step P(n) is added to the data sampled from the input task Tan, and K(n+1) types of data are output. In general, K(n+1) K(n). The obtained output data is used as input data of the next step P(n+1).

As a result of the surrogate simulation of the step P(n), the transition of the internal state of the step P(n) is also output. When processing of step P(n) is executed, a change in the state variable representing the internal state suggests a possibility of causing a problem such as deterioration of productivity. Among such internal states, an internal state represented by a state variable designated in advance is the “problem event” described above.

### (Configuration of Overall System S)

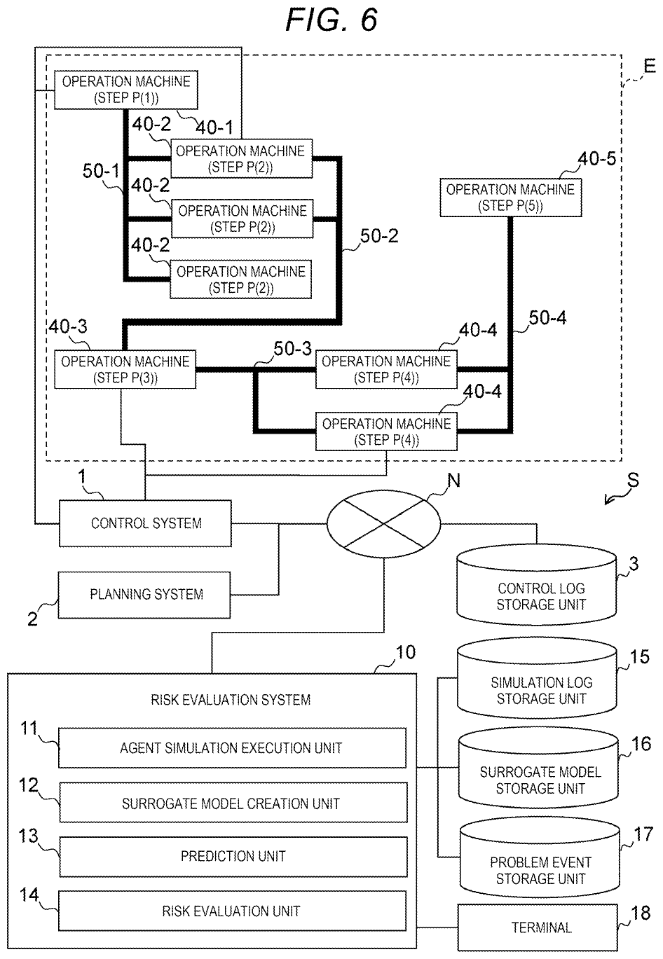

FIG. 6 is a diagram showing a configuration of the overall system S according to the present embodiment. In the present embodiment, an example of the overall system S will be described, in which a system that performs risk analysis of an operation schedule in an operation environment E and visualization of a risk analysis result is applied to a system that controls the operation environment E such as a factory or a warehouse.

The operation environment E includes an operation area, an operation machine, and an operator for performing each step operation on a target object. The operation machine and the operator are arranged for each step. In the operation environment E, an operation machine (step P(1)) 40-1, an operation machine (step P(2)) 40-2, an operation machine (step P(3)) 40-3, an operation machine (step P(4)) 40-4, and an operation machine (step P(5)) 40-5 are connected in series via conveyors 50 (50-1, 50-2, 50-3, and 50-4) in an execution order of the operation of steps P(1) to P(5) (FIG. 1).

The operation machine 40 represents an operation machine including personnel who perform the operation of each step P(n) (n=1 to 5). FIG. 6 shows that the operation of the step P(2) is performed in any of the plurality of operation machines (step P(2)) 40-2 connected in parallel. Similar applies to the step P(4) and the operation machine (step P(4)) 40-4.

The overall system S includes a control system 1, a planning system 2, a control log storage unit 3, a risk evaluation system 10, a simulation log storage unit 15, a surrogate model storage unit 16, a problem event storage unit 17, and a terminal 18. The control system 1, the planning system 2, the control log storage unit 3, and the risk evaluation system 10 are communicably connected via a network N.

The control log storage unit 3, the simulation log storage unit 15, the surrogate model storage unit 16, and the problem event storage unit 17 are storage areas such as databases. The control log storage unit 3 holds an execution log of processing and control executed by the control system 1 and the planning system 2. The simulation log storage unit 15 stores execution results of simulations by an agent simulation execution unit 11 and a prediction unit 13, and is provided for statistical analysis such as risk evaluation. The surrogate model storage unit 16 stores a surrogate model 16M. The problem event storage unit 17 stores the problem event table 17T (FIG. 4) and various related information.

The terminal 18 is a computer of an administrator such as a tablet terminal including a touch panel and a display, which is connected to the risk evaluation system 10 via a wireless communication line or a wired communication line.

The control system 1 and the planning system 2 constitute an operation scheduling instruction system such as a manufacturing execution system (MES) or a warehouse control system (WCS). The control system 1 outputs and controls an operation instruction to each operation machine in real time in accordance with an operation schedule calculated by the planning system 2. The planning system 2 calculates an operation schedule indicating an optimal procedure for performing the operation in steps P(1) to P(5).

The risk evaluation system 10 simulates an operation executed by the control system 1 in accordance with an operation schedule, and evaluates a risk of the operation. The risk evaluation system 10 includes the agent simulation execution unit 11, a surrogate model creation unit 12, the prediction unit 13, and a risk evaluation unit 14. The risk evaluation system 10 is connected to a console (not shown) that receives an operation of an administrator and outputs a processing status and a result.

The agent simulation execution unit 11 executes a simulation of the transition of the internal state of each step that appears due to the behavior and the interaction of the agent in each step under a predetermined assumption condition.

The surrogate model creation unit 12 creates the surrogate model 16M used by the prediction unit 13 in the preliminary phase so that the behavior of the agent simulation execution unit 11 can be imitated at a high speed. The surrogate model 16M is created for each step.

The surrogate model creation unit 12 stores operation results obtained by randomly giving various data to the agent simulation execution unit 11 in the simulation log storage unit 15. The data of the operation result includes a parameter of a machine operating condition, required time (delay due to operation) of each task, execution accuracy of each task, and the like.

In order to learn a transition model of the internal state, the surrogate model creation unit 12 learns the surrogate model 16M including the operation result and an order of the operation result. The internal state corresponding to the “problem event” is also learned, and the surrogate model 16M can output a determination result of an occurrence of the problem event.

Since the creation of the surrogate model 16M requires a lot of time for learning, the surrogate model 16M is executed in a preliminary phase before an actual time operation (system operation as a cyber physical system (CPS)) of the overall system S. The prediction unit 13 executes a surrogate calculation simulation of the agent simulation execution unit 11 using the surrogate model 16M at the time of actual time operation.

The risk evaluation unit 14 evaluates the risk of the operation to be evaluated based on the processing result by the prediction unit 13, and transmits the evaluation result to the terminal 18.

### (Surrogate Model Creation Processing)

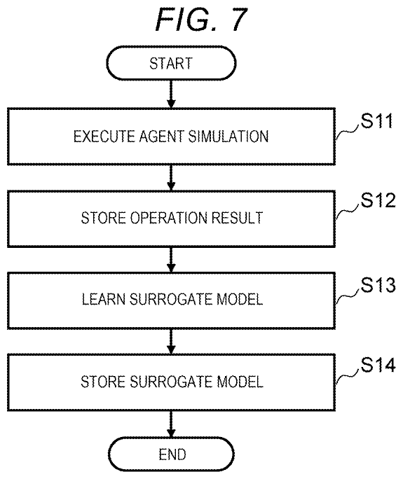

FIG. 7 is a flowchart showing an example of the surrogate model creation processing in the preliminary phase. The surrogate model creation processing is executed by the surrogate model creation unit 12 that receives an instruction from the administrator.

First, in step S11, the surrogate model creation unit 12 randomly provides data to the agent simulation execution unit 11, and causes the agent simulation execution unit 11 to execute agent simulation. Next, in step S12, the surrogate model creation unit 12 causes the simulation log storage unit 15 to store the operation result executed by the agent simulation execution unit 11 in step S11. Next, in step S13, the surrogate model creation unit 12 learns the surrogate model 16M, which is a transition model of the internal state of each step, based on the operation result accumulated in the simulation log storage unit 15 and the execution order thereof. Next, in step S14, the surrogate model creation unit 12 stores the surrogate model 16M learned in step S13 in the surrogate model storage unit 16.

### <Risk Analysis Processing>

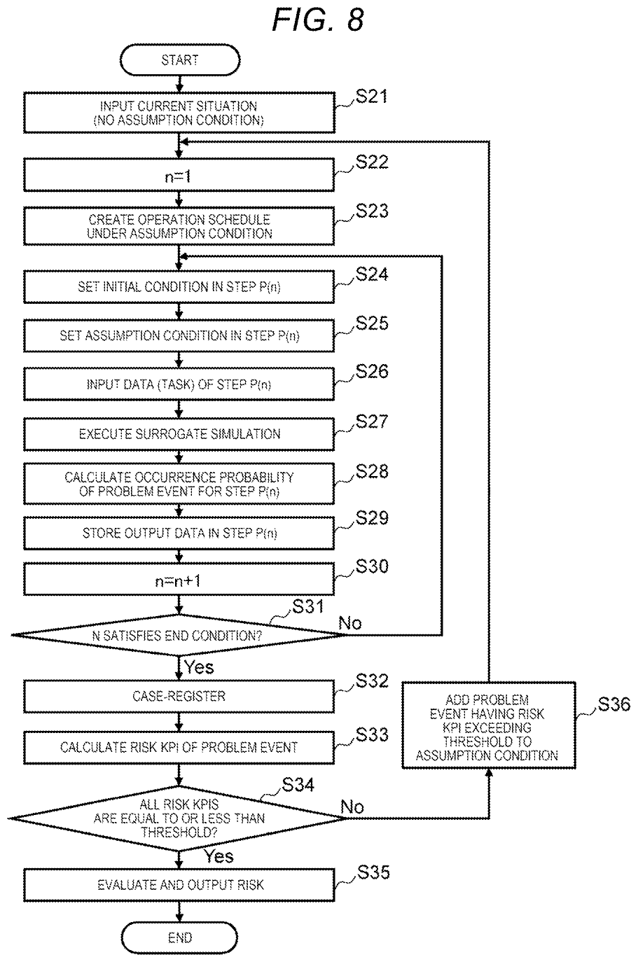

FIG. 8 is a flowchart showing an example of the risk analysis processing in an operation phase. In the operation phase, risk analysis and a report output of a problem with respect to an operation schedule are performed while actually controlling the operation machine 40 in accordance with the operation schedule and executing each step. The risk analysis processing is frequently executed by the prediction unit 13 and the risk evaluation unit 14 of the risk evaluation system 10 at a predetermined cycle (for example, once every several minutes), and the result is transmitted to the terminal 18 of the administrator.

In an actual operation of a factory, a warehouse, or the like, it is assumed that a task of one day required for the facility is divided into tens of batch units and processed. It is assumed that the batch operation includes a fixed element whose operation content is fixed in advance, and an unfixed element that is not determined until the number and contents of operation elements on the current day are just at the last moment, and is defined by a predicted value. Since there is an unfixed element, even when an operation schedule based on a current assumption condition is once created, it is necessary to grasp a problem event by frequently performing risk analysis, and to take measures such as review of the operation schedule.

First, in step S21, the prediction unit 13 inputs a current situation (no assumption condition). Next, in step S22, the prediction unit 13 sets an index n of the step to 1. Next, in step S23, the prediction unit 13 activates a scheduler (not shown) of the planning system 2, and creates an optimal operation schedule (start time, optimal resource allocation of the operation machine 40 and personnel, and the like) based on the operation plan including the predicted value under the current assumption condition. Each operation machine 40 operates in accordance with information from the scheduler of the control system 1 based on the operation plan. Then, the current situation is fed back from a sensor provided in each operation machine 40. The control system 1 advances the step while correcting the start time of the operation schedule, the resource allocation, and the like based on feedback information from the sensor.

Steps S24 to S31 are executed to predict a future transition of the operation schedule created in step S23. The prediction unit 13 receives the operation schedule created by the scheduler in step S23. The operation schedule includes information describing allocation and an order of each task to a batch unit, an operation machine number to which each task is specifically allocated, a resource allocation timing, and the like. Among these pieces of information, only information used as a parameter at the time of learning the surrogate model 16M is used as the time series data An,k (k=1, 2, . . . ) (FIG. 5) of the task Tan input to the surrogate model 16M that predicts the operation result of the step P(n).

In step S24, the prediction unit 13 sets an initial condition in the step P(n). Next, in step S25, the prediction unit 13 sets an assumption condition in the step P(n). The assumption condition is a condition of a problem event or the like that causes a decrease in productivity or the like in the step P(n).

Next, in step S26, the prediction unit 13 inputs data (task) of the step P(n) to the surrogate model 16M. The input data of the step P(n) is the output data of the step P(n−1), and a large quantity of input patterns are created with a basic value+a random error based on an error distribution of an output of the step P(n−1). Step S26 is repeated as many times as the number of input patterns. The input data (task) of the step P(1) is set to a given initial value.

Next, in step S27, the prediction unit 13 generates a plurality of output examples by executing a surrogate calculation simulation using the surrogate model 16M a predetermined number of trials under the current assumption condition. The predetermined number of trials is the same as the number of input patterns created in step S26. The output includes operation end time, information on productivity, problem event occurrence information, and the like. Step S27 is executed a plurality of times for each input in step S26, and the surrogate model 16M performs a probabilistic behavior and outputs a plurality of patterns for each input, thereby creating a large number of output examples. That is, the fluctuation of the prediction result is reproduced by executing the prediction by the surrogate model 16M a plurality of times for the same value.

Next, in step S28, the risk evaluation unit 14 calculates an occurrence probability of each problem event Qn,j for each step P(n) in the surrogate simulation in step S27. The occurrence probability of each of the problem events Qn,j is calculated based on the determination result of an occurrence of the problem event included in an output of the surrogate model 16M.

Next, in step S29, the prediction unit 13 obtains each output of the step P(n) in step S27, and stores the output in the simulation log storage unit 15 in association with a tag including a trial number for searching. Each output of the step P(n) is an input of the step P(n+1).

Next, in step S30, the prediction unit 13 increments the index n by 1. Next, in step S31, the prediction unit 13 determines whether n satisfies an end condition. In the present embodiment, since the target is the steps P(1) to P(5) (n=1 to 5), when n=6, the determination in step S31 is Yes, and the processing proceeds to step S32, and when n<6, the processing returns to step S24.

In step S32, the prediction unit 13 case-registers the execution result of the simulation of the loop of steps S24 to S31 in the simulation log storage unit 15 together with the assumption condition. In step S32, the assumption condition and the execution result are registered in association with each other for each loop of steps S22 to S34. As a result, it is possible to check in time series how the execution result changes in the process of sequentially incorporating the problem events into the assumption condition.

Next, in step S33, the risk evaluation unit 14 calculates KPIn,j that is a key performance index (KPI) of each problem event Qn,j from expression (1) based on the occurrence probability pn,j of each problem event Qn,j of each step P(n) calculated in step S28 and case-registered in the simulation log storage unit 15 in step S32. A, B, C, ka, and kb in the expression (1) are predetermined constants.

KPI_(n,j)=A/(1−p_(n,j)+k_a)×B/(t+k_b)×[[C·log]]c (1)

Expression (1) is an example, and KPIn,j may be an index based on another equation as long as KPIn,j is an index that increases as the occurrence probability pn,j increases, increases as the remaining time t to the handling plan operation decreases, and increases as a burden cost c at the time of occurrence increases.

Next, in step S34, the risk evaluation unit 14 determines whether all risk KPIs calculated in step S33 are equal to or less than a threshold θ. When all risk KPIs are equal to or less than the threshold θ (Yes in step S34), the risk evaluation unit 14 proceeds to step S35, and when there is at least one risk KPI that is greater than the threshold θ (No in step S34), the risk evaluation unit 14 proceeds to step S36.

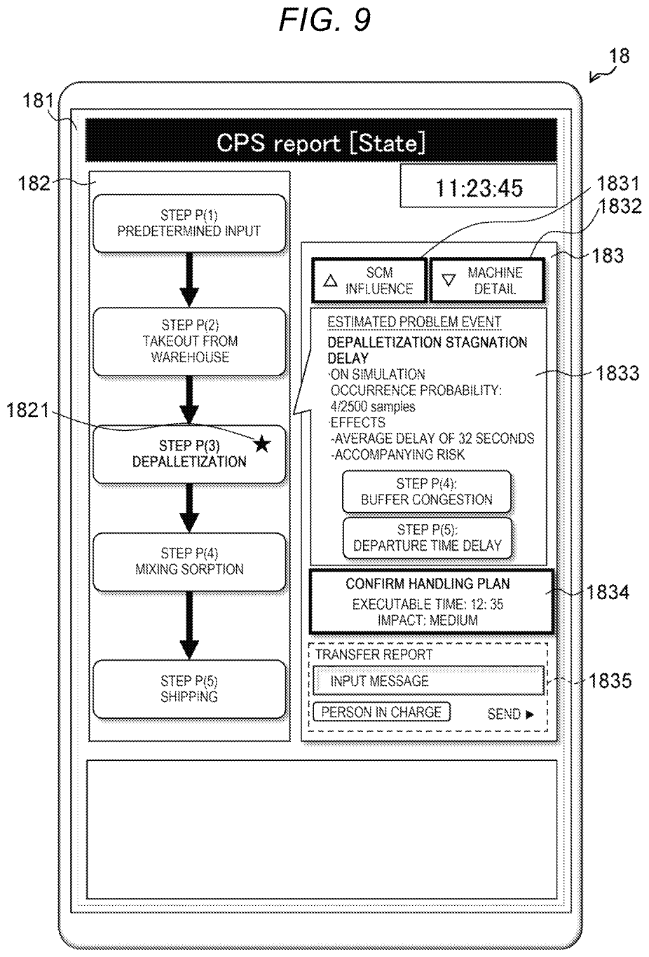

In step S35, the risk evaluation unit 14 performs an aggregation process of the simulation execution results case-registered in the simulation log storage unit 15 in step S32 to evaluate the risk of the operation. Then, the risk evaluation unit 14 creates data of a report screen that presents a risk evaluation result to the administrator, and transmits the data to the terminal 18. The aggregation processing targets an assumption condition, a problem event occurrence probability, information on a link to a “handling plan” of an operation schedule when a problem event occurs, a “handling cost” when a problem event occurs, a link to “another problem event to be propagated” at the time of occurrence of a problem event, and the like. Necessary information at the time of aggregation such as “handling plan”, “handling cost”, and “another problem event to be propagated” is stored in, for example, the problem event storage unit 17, and is referred to at the time of aggregation. A detailed example of the report screen will be described later with reference to FIGS. 9, 10, and 11.

On the other hand, in step S36, the risk evaluation unit 14 puts a problem event corresponding to the risk KPI exceeding the threshold θ in step S34 into a list of recalculation candidates in order to add the problem event to the assumption condition. The recalculation candidate list includes, for example, an identification number of a problem event, a value of a risk KPI, and execution data, and the problem event is sorted in descending order of the risk KPI. The risk evaluation unit 14 extracts a predetermined number of problem events in order from the top of the list of recalculation candidates (in order from the largest risk KPI) and adds the extracted problem events to the assumption condition.

Thereafter, in the processing of step S23 executed again, an operation schedule is created based on the assumption condition in which the problem event is incorporated. In the processing of step S23, when the handling plan is defined for the problem event, the operation schedule is re-created according to the handling plan, and when the handling plan is not defined, the operation schedule is re-created by an optimization processing (resource reallocation or the like) of the scheduler. Then, the processing of steps S24 to S34 are executed, and the case is added.

Step S35 may be executed on condition that it is calculation end time, in addition to the condition that the result of step S34 is Yes.

In step S26, although an uncertainty (indeterminity) of the input is represented by a plurality of patterns, the invention is not limited thereto, and the incertainty of the input may be represented by a probability distribution represented by a probability density function. Similarly, in step S29, although an uncertainty (indeterminity) of the output is represented by a plurality of patterns, the invention is not limited thereto, and the incertainty of the output may be represented by a probability distribution represented by a probability density function. That is, the input and output of the surrogate model 16M may be any of values of a plurality of patterns or a probability distribution.

### (Dashboard Display of Risk Analysis Result)

FIGS. 9, 10 and 11 are diagrams showing a terminal display example of the dashboard of the risk analysis result. FIGS. 9, 10, and 11 are examples of report screens of risk evaluation results for each step P(n) output in step S35 (FIG. 8). The risk is, for example, items such as an occurrence probability of a problem event in surrogate simulation, a damage cost when a problem event occurs, and another problem event that may occur due to the problem event. The dashboard of the risk analysis result is implemented by an application or a browser executed by the terminal 18.

As shown in FIG. 9, a step display 182 and a report display 183 are displayed on a display screen 181 of the terminal 18. In the step display 182, for example, all steps (steps P(1) to P(5)) (FIG. 1) of the SCM step S(2) that is a risk analysis target in the present example are displayed together with the operation order. In the step display 182, an identification mark 1821 (star mark in FIG. 9) for notifying “there is a risk” to the step in which a result of the risk analysis was determined such that the problem event may occur is displayed. “There is a risk of a certain degree or more” means, for example, that the value of the risk KPIn,j is equal to or more than the threshold θ.

When the identification mark 1821 is tapped, the report display 183 corresponding to the problem event for each type is unfolded and displayed. The report display 183 includes a SCM influence display button 1831 and a machine detail display button 1832.

When the SCM influence display button 1831 is tapped, a report display 1833 of a problem event predicted to influence the SCM step S(2) displayed in the step display 182 is displayed. In addition to the report display 1833, a handling plan confirmation button 1834 and a report transfer function display 1835 are displayed. The problem event displayed here is, for example, a predetermined number of problem events in which the risk KPI calculated in step S33 (FIG. 8) is higher.

In the report display 1833, “depalletization stagnation delay” is given as an assumed problem event that may occur in the future, and “the number of occurrences is four” (occurrence probability 4/2500) among 2500 trials of execution of the surrogate simulation (step S27 in FIG. 8). An “influence” of the “depalletization stagnation delay” in the step P(3) has a risk of “buffer congestion” in the step P(4) and “departure time delay” in the step P(5) as accompanying risks on the subsequent steps P(4) and P(5) because the step P(3) is delayed by “average delay of 32 seconds”. A numerical value of “average delay of 32 seconds” is an average value of the delay time simulated in each trial of “the number of occurrences is four”.

As the “influence” of the “depalletization stagnation delay” in the step P(3), the “average delay of 32 seconds” in the step P(3) is added to the assumption condition (step S36 (FIG. 8)), and the processing of steps S22 to S34 (FIG. 8) are executed again, whereby the “buffer congestion” in the step P(4) is predicted as a further “influence”. Further, by adding the “buffer congestion” of the step P(4) to the assumption condition and executing the processing of steps S22 to S34 again, the “departure time delay” of the step P(5) is predicted as the further “influence”. In this way, by adding the problem event to the assumption condition and executing steps S22 to S34, it is possible to predict the problem event spreading in a chain manner across the steps.

Although not shown, when the machine detail display button 1832 is tapped, a layout display of machines and personnel constituting the operation machine (step P(3)) 40-3 (FIG. 6) of the step P(3) in which the identification mark 1821 is displayed is displayed together with the operation order.

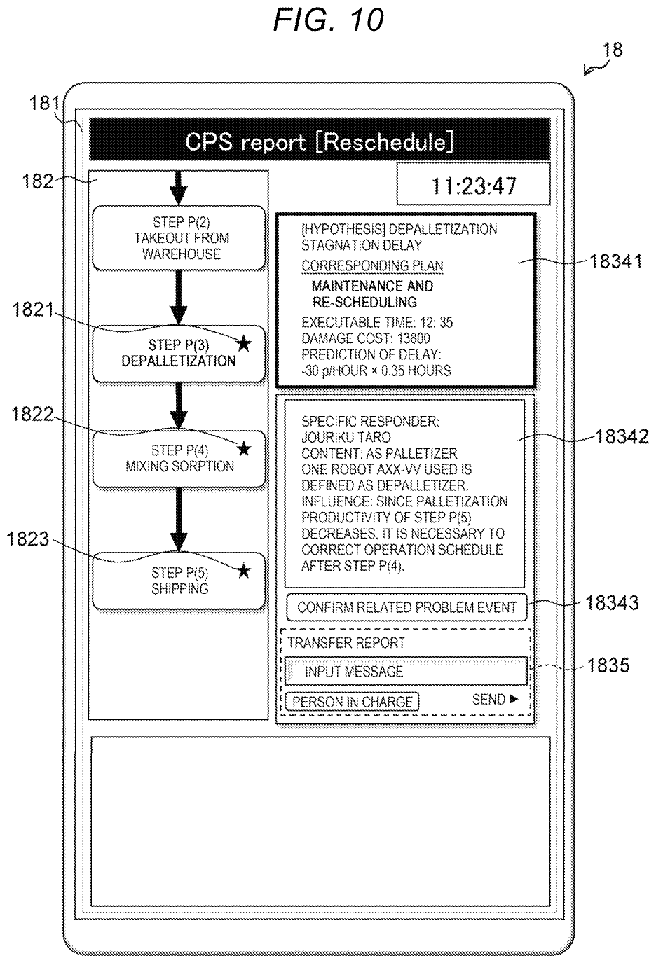

When the handling plan confirmation button 1834 is tapped, as shown in FIG. 10, a handling plan display 18341 indicating a handling plan for avoiding the problem event displayed in the report display 1833 is displayed. The handling plan is stored in the problem event storage unit 17 as information corresponding to the problem event. A detailed display of the handling plan will be described later with reference to FIG. 10.

The “executable time” displayed on the handling plan confirmation button 1834 is an execution deadline by which the problem event can be avoided in advance by executing the handling plan. “Impact” displayed on the handling plan confirmation button 1834 indicates the degree of a magnitude of the risk KPI when the handling plan is adopted.

When the handling plan is not defined for the problem event, the handling plan confirmation button 1834 is not displayed.

The report transfer function display 1835 receives an instruction to activate a function of designating a person in charge and transmit a report of the risk analysis result being displayed on the report display 183 together with a message. When the user of the terminal 18 confirms the handling plan and determines that the handling plan is necessary, the user of the terminal 18 makes contact with a concerned person.

When the handling plan confirmation button 1834 (FIG. 9) is tapped, as shown in FIG. 10, the handling plan display 18341, a detailed display 18342, and a related problem event confirmation button 18343 are displayed.

In the handling plan display 18341, “depalletization stagnation delay” is cited as a problem event that may occur in the future, and “maintenance (of machine)” and “rescheduling (of operation schedule)” are cited as handling plans. It is shown that the executable time of these handling plans is 12:35, the damage cost when a problem event occurs is 13800, and a delay expectation when a problem event occurs is a depalletization stagnation delay of “30 p/one hour×0.35 hour”. These pieces of information are obtained by performing an aggregation processing on the operation result of the surrogate simulation based on various pieces of information stored in the problem event storage unit 17, for example.

The detailed display 18342 shows a specific content of the handling plan displayed in the handling plan display 18341, and displays a responder, a content, an influence, and the like. These pieces of information are stored in, for example, the problem event storage unit 17. The detailed display 18342 shows a correspondence content in which “Taro Toaro” diverts “robot AXX-VV” from “palletizer” to “depletizer”. Since “palletization productivity of the step P(5) is reduced” by this diversion, “necessity of modification of the operation schedule after the step P(4)” is cited. These pieces of information are obtained by performing an aggregation processing on the operation result of the surrogate simulation based on various pieces of information stored in the problem event storage unit 17, for example.

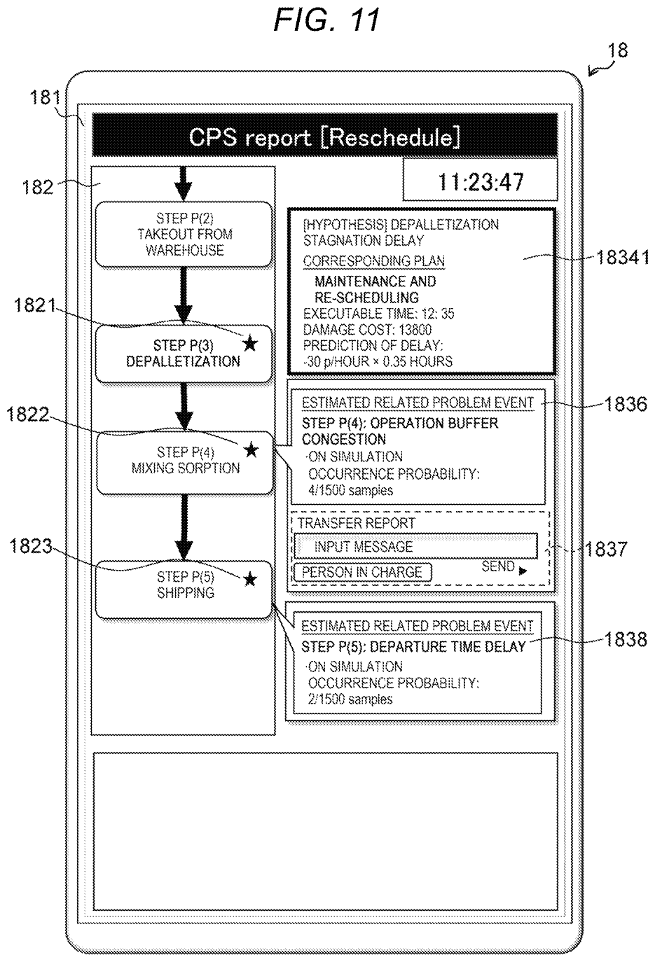

When the related problem event confirmation button 18343 is tapped, detailed information of a problem event (that is, accompanying risks “step P(4): buffer congestion” and “step P(5): departure time delay” displayed in the report display 1833 in the present example) (FIG. 9) derived from the problem event displayed in the handling plan display 18341 is displayed as shown in FIG. 11.

When the related problem event confirmation button 18343 is tapped, the identification mark 1822 is displayed corresponding to the problem event of “step P(4): buffer congestion”, and the identification mark 1823 is displayed corresponding to the problem event of “step P(5): departure time delay”.

FIG. 11 shows a report display 1836 of an assumed related problem event in the step P(4) and a report display 1838 of an assumed related problem event in the step P(5), which are displayed when the related problem event confirmation button 18343 is tapped.

In the report display 1836, an “operation buffer congestion” is given as a related problem event of the step P(4) that may occur in the future in relation to the “depalletization stagnation delay” of the step P(3), and “the number of occurrences is four” (occurrence probability 4/1500) among 1500 trials of the execution of the surrogate simulation (step S27 in FIG. 8). In the report display 1838, the “departure time delay” is given as a related problem event of the step P(5) that may occur in relation to the “depalletization stagnation delay” in the step P(3) and the “operation buffer congestion” in the step P(4), and “the number of occurrences is two” (occurrence probability: 2/1500) among 1500 trials of execution of the surrogate simulation (step S27 of FIG. 8). Other information may also be displayed in the report displays 1836 and 1838, and illustration thereof is omitted.

The report transfer function display 1837 receives an instruction to designate a person in charge and transmit a report of the risk analysis result being displayed on the report display 1836 together with a message. Although similar functions are also provided in the report display 1838, illustration thereof is omitted.

### Effect of Embodiment

In the present embodiment, a specific internal state that causes a decrease in productivity of an operation expressed on the agent simulation is defined as a problem event, and a surrogate calculation model of the agent simulation is constructed so that the problem event can be reproduced. Then, an input value having fluctuation (indeterminity) is input to the surrogate model of a step, and an output value having fluctuation (indeterminity) according to the indeterminity of the input value and the probabilistic behavior of the surrogate model is set as an input value of the surrogate model of the next step. Therefore, by quickly performing a simulation of the future trend of the operation and an occurrence of the problem event with respect to an enormous number of patterns, it is possible to quickly predict and evaluate a risk of the operation including an uncertain event.

It is possible to visualize a deviation of the operation progress from the operation schedule and the prediction result of an occurrence of the problem in the operation, to present presence or absence, an influence, and the like of an alternative plan including a rescheduling of the operation schedule to the user so as to be intuitively grasped, and to support a rapid and accurate decision-making with respect to the occurrence of the problem.

### (Hardware of Computer 1000)

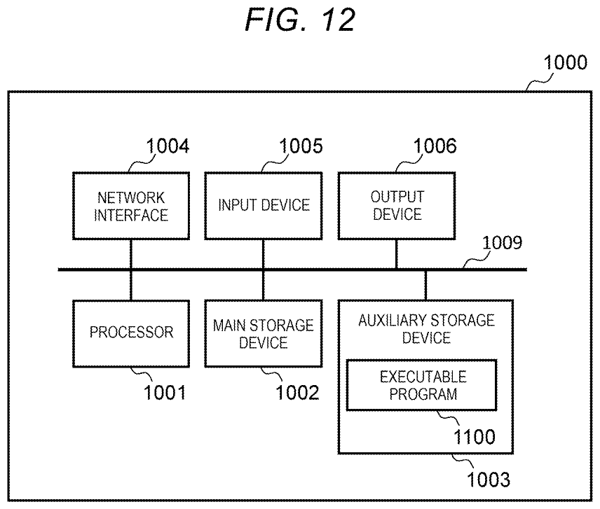

FIG. 12 is a hardware diagram showing a configuration example of the computer 1000. For example, a model creation apparatus including the agent simulation execution unit 11 and the surrogate model creation unit 12, an operation risk evaluation system including the prediction unit 13 and the risk evaluation unit 14, the terminal 18, or apparatuses obtained by appropriately integrating these units are implemented by the computer 1000.

The computer 1000 is a computer including a processor 1001 including a CPU, a main storage device 1002, an auxiliary storage device 1003, a network interface 1004, an input device 1005, and an output device 1006, which are connected to each other via an internal communication line 1009 such as a bus.

The processor 1001 controls an overall operation of the computer 1000. The main storage device 1002 includes, for example, a volatile semiconductor memory, and is used as a work memory of the processor 1001. The auxiliary storage device 1003 is a large-capacity nonvolatile storage device such as a hard disk drive, a solid state drive (SSD), or a flash memory, and is used to hold various programs and data for a long period of time.

The executable program 1100 stored in the auxiliary storage device 1003 is loaded into the main storage device 1002 when the computer 1000 is activated or when necessary, and the processor 1001 executes the executable program 1100 loaded into the main storage device 1002.

The executable program 1100 may be recorded on a non-transitory recording medium, read from the non-transitory recording medium by a medium reading device, and loaded into the main storage device 1002. Alternatively, the executable program 1100 may be acquired from an external computer via a network and loaded into the main storage device 1002.

The network interface 1004 is an interface device that connects the computer 1000 to each network in the system or enables the computer 1000 to communicate with another computer. The network interface 1004 includes, for example, a network interface card (NIC) such as a local area network (wired LAN) or a wireless LAN.

The input device 1005 includes a keyboard, a pointing device such as a mouse, and the like, and is used by the user to input various instructions and information to the computer 1000. The output device 1006 includes, for example, a display device such as a liquid crystal display or an organic electro-luminescence (EL) display, or an audio output device such as a speaker, and is used to present necessary information to the user when necessary.

The invention is not limited to the embodiment described above, and includes various modifications. For example, the embodiment described above is described in detail for easy understanding of the invention, and the invention is not necessarily limited to those including all the configurations described above. As long as there is no contradiction, a part of the configuration of one embodiment may be replaced with the configuration of another embodiment, and the configuration of one embodiment may be added to the configuration of another embodiment. A configuration can be added to, deleted from, replaced with, integrated, or distributed to a part of the configuration of each embodiment. The configurations and processing described in the embodiment can be appropriately distributed, integrated, or replaced based on a processing efficiency or a mounting efficiency.

What is claimed is:

1. An operation risk evaluation system for performing risk evaluation of an operation including steps, the system comprising:
a model storage unit configured to store a surrogate model that is a learned model of a relationship between an input that is a first feature amount of the operation and an output that is a second feature amount of the operation calculated by a predetermined simulation of one of the steps, the learned model being configured to surrogate for the predetermined simulation in which an output corresponding to an input having the same value has indeterminity different for each input;
a prediction unit configured to predict a plurality of the second feature amounts having indeterminity corresponding to the first feature amount having the same value in the step by repeatedly acquiring the second feature amount as the output from the surrogate model with the first feature amount as the input for a predetermined number of trials on the first feature amount having the same value; and
a risk evaluation unit configured to evaluate a risk of the operation in the step based on the plurality of second feature amounts having indeterminity predicted by the prediction unit.

2. The operation risk evaluation system according to claim 1, wherein
the predetermined simulation is an agent simulation, and
the surrogate model is a Bayesian neural network.

3. The operation risk evaluation system according to claim 1, wherein
the operation includes a plurality of the steps, and
the surrogate model surrogates for the predetermined simulation for each of the steps, and
the prediction unit predicts the plurality of the second feature amounts having indeterminity in one of the steps by inputting a plurality of the first feature amounts having indeterminity to the surrogate model of the step, and predicts the plurality of the second feature amounts having indeterminity in a next step by inputting the plurality of the second feature amounts having indeterminity predicted in the step as the plurality of the first feature amounts having indeterminity to the surrogate model of the next step.

4. The operation risk evaluation system according to claim 3, wherein
the indeterminity of the plurality of the first feature amounts and the indeterminity of the plurality of second feature amounts are represented by a probability distribution.

5. The operation risk evaluation system according to claim 3, wherein
the indeterminity of the plurality of the first feature amounts and the indeterminity of the plurality of the second feature amounts are represented by a set of a plurality of pattern values.

6. The operation risk evaluation system according to claim 1, wherein
the surrogate model further learns a learning of a relationship between the input that is the first feature amount and an output that is a transition of an internal state of the step calculated by the predetermined simulation,
the prediction unit predicts the transition of the internal state together with the plurality of the second feature amounts having indeterminity in the step using the surrogate model in an operation schedule created under a predetermined assumption condition, and
the risk evaluation unit determines whether the internal state predicted to transition by the prediction unit corresponds to a problem event defined in advance as a specific internal state that reduces productivity of the step.

7. The operation risk evaluation system according to claim 6, wherein
the risk evaluation unit calculates an occurrence probability of the problem event, and when a predetermined index based on the occurrence probability for evaluating a risk of the problem event exceeds a threshold, notifies a scheduler to re-create the operation schedule after adding the problem event to the predetermined assumption condition, and
the prediction unit re-predicts the transition of the internal state together with the plurality of the second feature amounts having indeterminity in the step based on the predetermined assumption condition to which the problem event is added.

8. The operation risk evaluation system according to claim 7, wherein
the risk evaluation unit generates data for notifying a user of information on at least one of a name of the problem event, an occurrence frequency of the problem event, the predetermined number of trials, an occurrence probability of the problem event, another problem event that occurs in a chain with the problem event, and a handling plan of the problem event when the internal state corresponds to the problem event, and transmits the data to a terminal of the user, and
the terminal displays a screen based on the received data.

9. A model creation apparatus for creating a prediction model for predicting a feature amount of an operation including steps, the apparatus comprising:
a simulation execution unit configured to execute a predetermined simulation of one of the steps using a first feature amount of the operation as an input and a transition of an internal state of the step and a second feature amount of the operation as an output; and
a surrogate model creation unit configured to create, as the prediction model, a surrogate model that is a learned model of a relationship between the input and the output and that surrogates for the predetermined simulation in which the second feature amount, which is an output corresponding to the input of the first feature amount having the same value, has indeterminity different for each input, wherein
the prediction model measures an occurrence of a problem event in the step when the internal state of the step transitions to a problem event defined in advance as a specific internal state that reduces productivity of the step using the first feature amount as an input.

10. An operation risk evaluation method for an operation risk evaluation system to perform risk evaluation of an operation including steps, wherein
the operation risk evaluation system includes a model storage unit configured to store a surrogate model that is a learned model of a relationship between an input that is a first feature amount of the operation and an output that is a second feature amount of the operation calculated by a predetermined simulation of one of the steps, the learned model being configured to surrogate for the predetermined simulation in which an output corresponding to an input having the same value has indeterminity different for each input, and
the method comprises:
a prediction step of predicting a plurality of the second feature amounts having indeterminity corresponding to the first feature amount having the same value in the step by repeatedly acquiring the second feature amount as the output from the surrogate model with the first feature amount as the input for a predetermined number of trials on the first feature amount having the same value; and
a risk evaluation step of evaluating a risk of the operation in the step based on the plurality of second feature amounts having indeterminity predicted in the prediction step.

11. The operation risk evaluation method according to claim 10, wherein
the predetermined simulation is an agent simulation, and
the surrogate model is a Bayesian neural network.

12. The operation risk evaluation method according to claim 10, wherein
the operation includes a plurality of the steps, and
the surrogate model surrogates for the predetermined simulation for each of the steps, and
the prediction step predicts the plurality of the second feature amounts having indeterminity in one of the steps by inputting a plurality of the first feature amounts having indeterminity to the surrogate model of the step, and predicts the plurality of the second feature amounts having indeterminity in a next step by inputting the plurality of the predicted second feature amounts having indeterminity in the step as the plurality of the first feature amounts having indeterminity to the surrogate model of the next step.

13. The operation risk evaluation method according to claim 12, wherein
the indeterminity of the plurality of first feature amounts and the indeterminity of the plurality of second feature amounts are represented by a probability distribution.

14. The operation risk evaluation method according to claim 12, wherein
the indeterminity of the plurality of the first feature amounts and the indeterminity of the plurality of the second feature amounts are represented by a set of a plurality of pattern values.

15. The operation risk evaluation method according to claim 10, wherein
the surrogate model further learns a learning of a relationship between the input that is the first feature amount and an output that is a transition of an internal state of the step calculated by the predetermined simulation,
the prediction step predicts the transition of the internal state together with the plurality of the second feature amounts having indeterminity in the step using the surrogate model in an operation schedule created under a predetermined assumption condition, and
the risk evaluation step determines whether the internal state predicted to transition in the prediction step corresponds to a problem event defined in advance as a specific internal state that reduces productivity of the step.

16. The operation risk evaluation method according to claim 15, wherein
the risk evaluation step calculates an occurrence probability of the problem event, and when a predetermined index based on the occurrence probability for evaluating a risk of the problem event exceeds a threshold, notifies a scheduler to re-create the operation schedule after adding the problem event to the predetermined assumption condition, and
the prediction step re-predicts the transition of the internal state together with the plurality of the second feature amounts having indeterminity in the step based on the predetermined assumption condition to which the problem event is added.

17. The operation risk evaluation method according to claim 16, wherein
the risk evaluation step generates data for notifying a user of information on at least one of a name of the problem event, an occurrence frequency of the problem event, the predetermined number of trials, an occurrence probability of the problem event, another problem event that occurs in a chain with the problem event, and a handling plan of the problem event when the internal state corresponds to the problem event, and transmits the data to a terminal of the user, and
the terminal displays a screen based on the received data.

18. A recording medium storing an operation risk evaluation program that causes a computer to function as the operation risk evaluation system according to claim 1.
